(19) United States
(12) Patent Application Publication
(10) Pub. No.: US 2007/0148988 A1
(43) Pub. Date: Jun. 28, 2007

(54) Fabrication method for alignment film

(75) Inventors: Chih-Wei Chen, Hsinchu Hsien (TW); Chun-Hung Lin, Hsinchu Hsien (TW); Huang-Chin Tang, Hsinchu Hsien (TW); Yun-Chuan Tu, Hsinchu Hsien (TW); Ying-Fang Chang, Hsinchu Hsien (TW); Yu-Jung Shih, Hsinchu Hsien (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/505,855

(22) Filed: Aug. 18, 2006

(30) Foreign Application Priority Data
Dec. 23, 2005 (TW) 094146007

(51) Int. Cl. H01L 21/469; G02F 1/1337

(52) U.S. Cl. 438/778; 438/608; 349/123

(57) ABSTRACT

A fabrication method for an alignment film is proposed. A film is deposited on a substrate by an atmosphere plasma in a predetermined direction at a predetermined angle, while moving the substrate and the atmosphere plasma relative to each other. Thereby, a uniform isotropic alignment film with strong anchoring energy is formed and the pre-tilt angle can be designed according to the need. Problems such as static charge and dust generated during a conventional rubbing process are prevented. In addition, since the above fabrication method eliminates the need of vacuum devices that are required in conventional ion beam alignment and plasma beam alignment processes, the fabrication method can be used to fabricate large sized alignment film. Moreover, fabrication cost is lowered through the use of the fabrication method.

### BACKGROUND OF THE INVENTION

1. Field of the Invention

The present invention relates generally to a substrate surface alignment technology, and more particularly, to a fabrication method for an alignment film.

2. Description of Related Art

Liquid crystal displays are receiving much more attention as an advanced display device that can substitute for a cathode ray tube (CRT). The fabrication of a conventional TFT liquid crystal display mainly includes: an array process for fabricating transistors on a glass substrate; a cell process for joining the arrayed back substrate and a front substrate that is fitted with a color filter, wherein space between the substrates is filled with liquid crystal; and a module assembly process which involves connecting additional components such as polarizers and backlight units to the fabricated glass panel. Therein, the liquid crystal alignment during the cell process is very important. The liquid crystal alignment can make the liquid crystal molecules have a predetermined tilt direction such that liquid crystal molecules can rotate along the same direction when an electric filed is applied. Thereby, the liquid crystal molecules can be aligned more uniformly. In addition, the liquid crystal process is closely related to high quality display characteristics of liquid crystal displays such as view angle, response speed, contrast ratio and color quality. Conventional alignment technology mainly includes rubbing alignment and non-rubbing alignment.

The conventional rubbing alignment that is widely used in the industry is shown in FIG. 1. A substrate 1 such as an ITO glass substrate is disposed on a platform and moved in a single direction. A Rayon 15 with short and compact fibers is fixed to circumference of a roller 13. The roller 13 rotates several hundreds of rounds per minute with its fibers being pressed into an alignment film 11 made of PI preformed on the substrate 1 and rubbing the surface of the alignment film 11 at a high speed. Thus, molecules on the alignment film 11 are arranged regularly in the rubbing direction, and accordingly the liquid crystal molecules filled and sealed in subsequent process can be uniformly aligned through an interface force.

The benefits are that the rubbing alignment has short operation time, can be operated at an ambient temperature and is good for mass production. However, the rubbing alignment can generate dust, static charging and cause rubbing defect during the rubbing process, which leads to low product yield and low product reliability. Theses problems prevent the rubbing alignment from being used in fabricating liquid crystal devices that have high brightness, large size and wide view angle.

Accordingly, non-rubbing alignment technology such as photo alignment, ion alignment and plasma alignment has gradually become the mainstream.

The photo alignment method uses an ultraviolet light source having anisotropic energy to irradiate a polymer film made of such as PI so as to induce anisotropic photo-polymerization, photo-isomerization, or photo-degradation of the polymer molecules on surface of the polymer film. Thereby, anisotropically distributed van der waals forces can be generated for further making liquid crystal molecules arranged in a desired way. The photo alignment method mainly uses a linear polarized ultraviolet light source that is generated by polarizing an ultraviolet light source. Since energy anisotropy of the ultraviolet light source is high, it can efficiently induce anisotropic photoreaction on the surface of the polymer film. However, the photo alignment method has some bottlenecks such as anchoring energy and image persistence. In addition, lifetime of lamps used in an exposure machine and flicker of the light source can adversely affect the alignment stability.

According to an ion beam alignment process, an in-organic or organic alignment film is bombarded by an ion beam at a predetermined angle so as to induce selective broken bonds on surface of the alignment film. An ion beam alignment device mainly includes a vacuum cavity, an ion source, a neutralizing device for neutralizing ion and a movable and rotatable platform on which a glass substrate can be disposed.

FIG. 2 shows an ion beam alignment device 2 according to U.S. Pat. No. 6,665,033 B2 disclosed by IBM Corporation, wherein a Kaufman-type ion gun 23 is used in a vacuum cavity 21 of the ion beam alignment device 2 for generating an ion beam. The ion beam alignment device 2 further comprises a neutralizing device 25. Plasma is generated inside the ion gun 23 first, and positive ions are separated from the plasma, passed through an accelerator and flies away from the ion gun 23 at a high speed, thereby generating an ion beam to be used in an alignment process. To prevent too many charges from being accumulated on the alignment film, the ion beam needs to be neutralized by electrons that are excited by hot filament before aligning the alignment film.

Since the ion beam alignment process needs high vacuum and static charge eliminating device, it not only increases the process cost but also increases the difficulty of producing large sized liquid crystal panel. In addition, the problem of the lifetime of the ion gun has not been solved yet. Therefore, the ion beam alignment technology still stays at an experimental stage.

The plasma beam alignment is also called as a particle beam alignment. The plasma beam comprises ions, electrons, neutralized gas and ultraviolet light. The initial concept of the plasma beam alignment comes from aerospace close drift technology of the former Soviet Union.

The plasma beam alignment generates plasma with a DC plasma system. Then, the ion group of the plasma is driven by a positive offset intensive electric field generated by a positive electrode of the DC plasma system so as to generate an anode layer for alignment. Moreover, the plasma modifies the surface of the alignment film. The plasma alignment prevents static charging and dust from generating, and the alignment film has properties of photo-stability and alignment-stability. Moreover, the range of the pre-tilt angle is controllable. The anchoring energy of the plasma beam alignment can reach a similar level as the photo alignment. For example, U.S. Pat. No. 6,563,560 B2 discloses a method that vapor-deposits an alignment film in an oblique direction in a vacuum environment.

However, because both the conventional ion beam alignment and the plasma beam alignment need vacuum plasma devices, the process cost is increased and the alignment process is complicated. Also, reaching a vacuum state takes a lot of time. In addition, to fabricate large sized panel, special devices are needed. Therefore, the plasma beam alignment also stays at an experimental stage.

Accordingly, there exists a strong need in the art for a method to solve the drawbacks of the above-described conventional technology.

### SUMMARY OF THE INVENTION

Accordingly, an objective of the present invention to provide a fabrication method for an alignment film with simplified fabrication steps.

Another objective of the present invention is to provide a fabrication method for an alignment film, which can prevent static charging and dust.

A further objective of the present invention is to provide a fabrication method for an alignment film, which can facilitate fabrication of large-sized alignment film.

Still another of the present invention is to provide a low-cost fabrication method for an alignment film.

In order to attain the above and other objectives, a fabrication method for an alignment film is proposed, which comprises: providing a substrate; and depositing a film on surface of the substrate with an atmosphere plasma in a predetermined direction at a predetermined angle, while moving the substrate surface and the atmosphere plasma relative to each other, so as to form a uniform alignment film with a uniform orientation.

The alignment film can be an organic film, an inorganic film, or an organic-inorganic hybrid film. In a preferred embodiment, the alignment film is made of high molecular polymer, nitride, oxide or diamond like film. Therein, the high molecular polymer can be selected from the group consisting of polyimide and derivatives thereof, acryl and PVCN; the nitride can be a nitrogen-silicon compound; and the oxide can be one of the group consisting of SiOₓ, Al₂O₃, CeO₂, SnO₂, ZnTiO₂ and InTiO₂.

The substrate is disposed on a platform and moved in a single direction or in reciprocal manner relative to the atmosphere plasma. Preferably, the predetermined angle between the atmosphere plasma and the normal line of the surface of the substrate ranges from 0° to less than 90°.

The atmosphere plasma can be a high-energy ion source generated by an atmosphere plasma generating device under ambient pressure or rough vacuum. The rough vacuum ranges between 100 Torr and 700 Torr. The device for generating the atmosphere plasma is one selected from a corona discharge, an atmospheric pressure glow discharge, an atmospheric pressure plasma jet, a plasma torch, a surface dielectric is barrier discharge, a coplanar diffuse surface discharge and a ferroelectric discharge. The ion source can be composed of electrons, ions, free radicals, neutral particles, or a combination of at least two groups thereof. The processing gas used in generating the plasma by the device can be dissociated under ambient pressure or rough vacuum environment. Preferably, the processing gas is selected from the group consisting of air, dry air, oxygen, nitrogen, argon, water vapor and helium. In addition, the atmosphere plasma dissociates a precursor to deposit the film on the surface of the substrate. The precursor can be an aqueous precursor or a gaseous precursor.

The substrate is a glass substrate. The substrate can further comprise a conductive layer made of such as ITO.

Through the present invention, a uniform alignment film with strong anchoring energy can be formed and the pre-tilt angle can be designed according to the need. Static charging and dust problems in the conventional rubbing process are prevented. By using thinner and lighter atmosphere plasma generating devices instead of vacuum devices that are required in conventional ion beam alignment and plasma beam alignment processes, the present invention saves vacuum-reaching time, simplifies the fabrication process, reduce the fabrication cost, and further facilitates the fabrication of large sized liquid crystal panel in future.

### BRIEF DESCRIPTION OF DRAWINGS

FIG. 1 (PRIOR ART) is a diagram of a conventional rubbing alignment process;

FIG. 2 (PRIOR ART) is a diagram of an ion beam alignment device disclosed by U.S. Pat. No. 6,665,033; and

FIGS. 3A and 3B are diagrams showing flow process of a fabrication method for an alignment film according to the present invention.

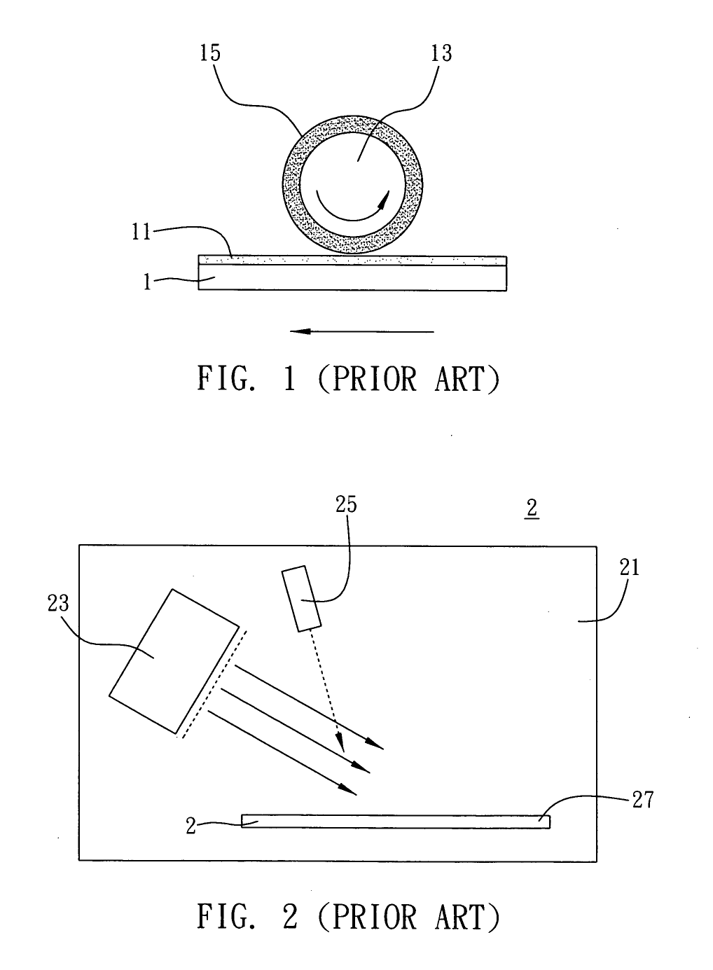

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be devised without departing from the spirit of the present invention.

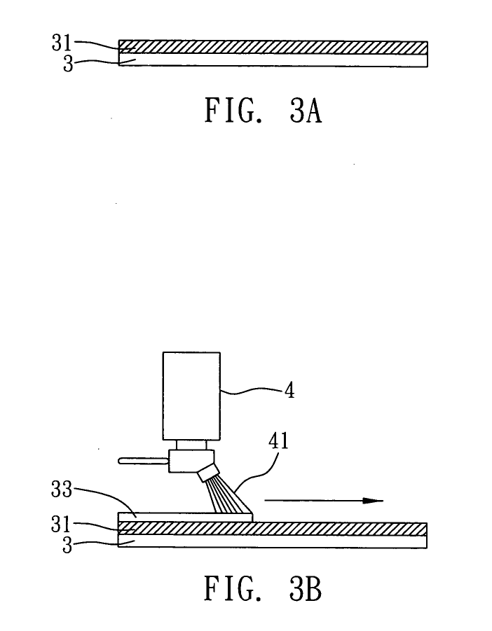

FIGS. 3A and 3B show a fabrication method for an alignment film according to the present invention. In the present embodiment, an atmospheric pressure plasma jet 4 is used to generate plasma, which can further be used in combination with a reciprocally moving platform, a material storing and releasing device in connection with the atmospheric pressure plasma jet and a control device for controlling the operation of alignment processing and material releasing. Besides an atmospheric pressure plasma jet, other device such as a corona discharge, an atmospheric pressure glow discharge, a plasma torch, a surface dielectric barrier discharge, a coplanar diffuse surface discharge and a ferroelectric discharge can also be used for generating the plasma.

Referring to FIG. 3A, a substrate 3 with a conductive layer 31 is provided first. In the present embodiment, the substrate 3 is a glass substrate applied in a liquid crystal panel, and the conductive layer 31 is made of Indium Tin Oxide (ITO). That is, the substrate 3 with the conductive layer 31 in the present embodiment is an ITO glass substrate. But it is not limited thereto.

Subsequently, as shown in FIG. 3B, an atmosphere plasma 41 generated by the atmospheric pressure plasma jet 4 deposits a film on the conductive layer 31 of the substrate 3 in a predetermined direction at a predetermined angle while the atmosphere plasma 41 and the substrate surface are moved relative to each other such that a uniform alignment film 33 with uniform orientation can be formed. In the present embodiment, the substrate 3 is disposed on a platform (not shown) and moved in a single direction or in a reciprocal manner relative to the atmosphere plasma such that the atmosphere plasma 41 can deposit the film on the surface of the substrate 3 in a predetermined direction at a predetermined angle. Therein, the predetermined angle is defined as an angle between the atmosphere plasma 41 and the normal line of the surface of the substrate 3 ranging from 0° to less than 90°.

The alignment film 33 formed through the above process can be an organic film, an inorganic film or an organic-inorganic hybrid film. In other embodiments, the alignment film 33 can be made of high molecular polymer, nitride, oxide or diamond like film. Therein, the high molecular polymer can be selected from the group consisting of polyimide and derivatives thereof, acryl and PVCN; the nitride can be a nitrogen-silicon compound; and the oxide can be one of the group consisting of SiOₓ, Al₂O₃, CeO₂, SnO₂, ZnTiO₂ and InTiO₂.

The atmosphere plasma 41 is a high-energy ion source generated by the device 4 under an ambient pressure. Alternatively, the atmosphere plasma 41can be generated under a rough vacuum environment ranging between 100 Torr and 760 Torr.

The ion source can be composed of electrons, ions, free radicals or neutral particles, or a combination of at least two groups thereof. In addition, the processing gas used by the device 4 in generating the plasma is a dissociatable gas under ambient pressure or rough vacuum environment, such as air, dry air, oxygen, nitrogen, argon, water vapor or helium. To prevent characteristic of the alignment film from fading away, a hydrogen-containing gas can be used during alignment process for passivating the alignment film, wherein hydrogen atoms are attached to dangling bonds in the plasma deposited film so as to keep the pre-tilt angle stable.

The fabrication method for an alignment film of the present invention vapor-deposits a uniform alignment film 33 with uniform orientation on surface of a substrate 3 through using an atmosphere plasma generated by an atmosphere plasma generating device as a high-energy ion source in a predetermined direction at a predetermined angle while moving the atmosphere plasma 41 and the substrate surface relative to each other, which not only can make the filled and sealed liquid crystal molecules be arranged in a uniform orientation, but also can change photoelectric properties such as pre-tilt angle of the liquid crystal molecules by changing process parameters.

In addition, using the atmosphere plasma as an ion source has an 1o advantage of cell patterning. Even size of the substrate is increased, the alignment layer can still be kept uniform by moving the platform.

Through the present invention, a uniform alignment film with strong anchoring energy can be formed and the pre-tilt angle can be designed according to the need. Static charging and dust problems in the conventional rubbing process are prevented. Further, by using thinner and lighter atmosphere plasma generating devices instead of vacuum devices that are required in conventional ion beam alignment and plasma beam alignment processes, the present invention saves vacuum-reaching time., simplifies the fabrication process, and further facilitates the fabrication of large sized liquid crystal panel in future. Moreover, fabrication cost is lowered through the present invention.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A fabrication method for an alignment film, comprising:
providing a substrate; and
depositing a film on the substrate with an atmosphere plasma in a predetermined direction at a predetermined angle, while moving the substrate and the atmosphere plasma relative to each other, so as to form a uniform alignment film with a uniform orientation.

2. The fabrication method of claim 1, wherein the alignment film is one of an organic film and an inorganic film.

3. The fabrication method of claim 1, wherein the alignment film is an organic-inorganic hybrid film.

4. The fabrication method of claim 1, wherein the substrate is disposed on a platform and moved in a single direction relative to the atmosphere plasma.

5. The fabrication method of claim 1, wherein the substrate is disposed on a platform and moved back and forth relative to the atmosphere plasma.

6. The fabrication method of claim 1, wherein the predetermined angle is defined as an angle between the atmosphere plasma and a normal line of the substrate ranging from 0° to less than 90°.

7. The fabrication method of claim 1, wherein the atmosphere plasma is a high-energy ion source generated by an atmosphere plasma generating device under a pressure environment which is ambient pressure or rough vacuum.

8. The fabrication method of claim 7, wherein the rough vacuum ranges between 100 Torr and 700 Torr.

9. The fabrication method of claim 7, wherein the atmosphere plasma generating device is one of a corona discharge, an atmospheric pressure glow discharge, an atmospheric pressure plasma jet, a plasma torch, a surface dielectric barrier discharge, a coplanar diffuse surface discharge and a ferroelectric discharge.

10. The fabrication method of claim 7, wherein the ion source is formed by a component selected from the group consisting of electrons, ions, free radicals and neutral particles.

11. The fabrication method of claim 7, wherein the ion source is formed by at least two components selected from the group consisting of electrons, ions, free radicals and neutral particles.

12. The fabrication method of claim 7, wherein a gaseous source used for the atmosphere plasma generating device to generate the atmosphere plasma is one of air, dry air, oxygen, nitrogen, argon, water vapor and helium.

13. The fabrication method of claim 7, wherein the atmosphere plasma generating device adopts air dissociated under one of an ambient pressure environment and a rough vacuum environment to generate the atmosphere plasma.

14. The fabrication method of claim 1 further comprising pre-forming a conductive layer on the substrate.

15. The fabrication method of claim 14, wherein the substrate is a glass substrate.

16. The fabrication method of claim 15, wherein the conductive layer is made of Indium Tin Oxide (ITO).

17. The fabrication method of claim 1, wherein the substrate is a glass substrate applied to a liquid crystal panel.

18. The fabrication method of claim 1, wherein the atmosphere plasma is used to dissociate a precursor to deposit the film on the substrate.

19. The fabrication method of claim 18, wherein the precursor is one of an aqueous precursor and a gaseous precursor.

20. The fabrication method of claim 1, wherein the substrate is a glass substrate.
